(19) United States
(12) Patent Application Publication
(10) Pub. No.: US 2008/0232044 A1
(43) Pub. Date: Sep. 25, 2008

(54) Apparatus and Method For Adding a Monitor To a Display System

(76) Inventor: Jerry Moscovitch, Toronto (CA)

Correspondence Address: MASS ENGINEERED DESIGN INC., 474 WELLINGTON STREET WEST, TORONTO, ON, M5V-1E3, CA

(21) Appl. No.: 10/597,109

(22) PCT Filed: Jan. 12, 2005
(86) PCT No.: PCT/CA2005/000039

§ 371 Date: Jul. 12, 2006

Related U.S. Application Data
(60) Provisional application No. 60/535,495, filed on Jan. 12, 2004.

(51) Int. Cl. H05K 7/00; G06F 1/16; H05K 5/00; B23P 11/00

(52) U.S. Cl. 361/681; 29/428

(57) ABSTRACT

A kit for adding a monitor to a display system configured to support multiple monitors is described, where the display system has at least one support member, and at least one electrical port associated with each support member. The kit includes a mounting bracket adapted to secure the monitor to one of the at least one support member, and an electrical connector adapted to electrically connect the monitor to one of the at least one electrical port corresponding to the one support member.

### FIELD OF THE INVENTION

The present invention relates to multiple monitor display systems, and more particularly to retrofitting monitors thereto.

### BACKGROUND OF THE INVENTION

Multi-monitor display systems are well known. Such systems provide two or more monitors, often secured to a common base having support members for each monitor. The monitors are generally operatively connected to a computer system, so that a first image may be displayed on a first monitor, and a second image may be displayed on a second monitor. This arrangement can facilitate activities, such as comparing two documents, which would be more difficult if only a single monitor were used, particularly where the single monitor can only effectively display one document at a time. Alternatively, a single image may be spread across two monitors. It is also known for such monitors to be adapted for removable attachment to the support members.

An exemplary multi-monitor display system is described in U.S. Pat. No. 6,343,006 to Moscovitch et al., which is hereby incorporated by reference in its entirety.

Typically, the monitors used in multi-monitor display systems are flat-panel monitors. The term “flat-panel” does not refer to the surface of the screen, but to the fact that the monitor has a generally rectangular, tablet-like shape, rather than the generally box-like shape of traditional cathode ray tube (CRT) monitors. Flat-panel monitor types include liquid crystal display (LCD) plasma screens, organic light emitting diode (OLED) among others. Flat-panel monitors are frequently used in multi-monitor display systems because they are relatively compact and lightweight. Accordingly, it is preferred that flat-panel monitors be used with the present invention. Other display types may also be used.

One problem often faced by a customer making an initial purchase of a multi-monitor display system is whether to purchase a single monitor or a multi-monitor system. A customer may face similar dilemmas in choosing between multi-monitor systems (e.g. between a two-monitor and a three-monitor system). Multi-monitor systems are typically more costly, and the customer is often uncertain as to whether such a system is needed. If the customer purchases a single-monitor system, however, and then realizes (after any return period has expired) that a multi-monitor system would be advantageous, the customer may have to buy a complete multi-monitor system, with the monitor from the first, single-monitor system being a wasted expense.

### SUMMARY OF THE INVENTION

Described herein is a kit that allows a monitor to be adapted for use in a multi-monitor display system. As used herein, the term monitor includes any device used to electronically display information. A monitor, for example, can include the display of a notebook computer, a handheld video game, a personal digital assistant (PDA), a telephone, or a video camera. Thus, an owner of a one-monitor display system wishing to acquire a two-monitor system, for example, need not purchase a display system having two monitors. Instead, the consumer purchases the kit, together with just one monitor and supporting equipment. The kit allows the consumer to use his or her existing monitor from the one-monitor system as part of a two-monitor system, thus obviating the need to buy two new monitors.

In particular, a kit for adding a monitor to a display system configured to support multiple monitors, where the display system has at least one support member, and at least one electrical port is described herein. The kit includes a mounting bracket adapted to secure the monitor to the at least one support member. the kit also includes an electrical connector adapted to electrically connect the monitor to the at least one electrical port.

Also described herein is a method of retrofitting a monitor for a display system configured to support multiple monitors, where the display system has at least one support member. The method includes securing a mounting bracket to the monitor, and mounting the monitor on the display system by securing the mounting bracket to the at least one support member.

### BRIEF DESCRIPTION OF THE DRAWINGS

FIG. 1 is a perspective, partly exploded view of a multi-monitor display system.

FIG. 2 is an exploded perspective view of a bracket used to mount a monitor to a display system, secured to a monitor.

FIG. 3 is an exploded perspective view of a single-monitor display system showing a support structure, a support member and a support element.

FIG. 4 is a side view of a bracket used to mount a monitor to a display system.

FIG. 5 is a front view of a bracket used to mount a monitor to a display system.

FIG. 6 is a top view of a bracket used to mount a monitor to a display system.

FIG. 7 is a side cross-sectional view of a bracket used to mount a monitor to a display system, taken along the line A-A in FIG. 5.

FIG. 8 is a bottom view of a bracket used to mount a monitor to a display system.

FIG. 9 is a top view of a support element.

FIG. 10 is a front view of a support element.

FIGS. 11A and 11B show a single-monitor display system, and a dual-monitor system resulting from upgrading the single-monitor system in accordance with the present invention.

FIG. 12 is an aspect of a modular support structure.

FIG. 13 is an arm member for use with a modular support structure.

FIG. 14 is a modular support structure configured with an arm member to support two monitors.

FIG. 15 is a modular support structure configured with two arm members to support three monitors.

FIG. 16 is a modular support structure configured with three arm members to support four monitors.

FIG. 17 is a top view of a mounting plate for mounting a monitor to a display system.

FIG. 18 is a front view of a mounting plate for mounting a monitor to a display system.

FIG. 19 is a receiving element for receiving a monitor having a mounting plate.

FIG. 20 is an embodiment of a mounting bracket system according to the present invention.

FIG. 21 is a side view of a monitor.

FIG. 22 is a rear view of a monitor.

FIG. 23 is a top view of a monitor.

FIG. 24 is a rear view of a monitor.

FIG. 25 is a rear view of a monitor.

FIG. 26 is a perspective view of a multi-monitor display system having combined video signal/power cables.

FIG. 27 is a rear view of a monitor.

FIG. 28 shows an electrical connector cable.

FIG. 29 is a perspective view of a multi-monitor display system having separate video signal and power cables.

FIG. 30 shows an electrical connector cable.

FIG. 31 is a rear view of a monitor.

FIG. 32 is a rear view of a first embodiment of a plug element.

FIG. 33 is a side view of a first embodiment of a plug element.

FIG. 34 is a rear view of a second embodiment of a plug element.

FIG. 35 is a side view of a second embodiment of a plug element.

FIG. 36 is a rear view of a first embodiment of an adaptor member.

FIG. 37 is a rear view of a second embodiment of an adaptor member.

FIG. 38 is a side view of a monitor and a monitor support.

FIG. 39 is a side view of a monitor and a monitor support.

### DETAILED DESCRIPTION OF THE PREFERRED EMBODIMENTS OF THE INVENTION

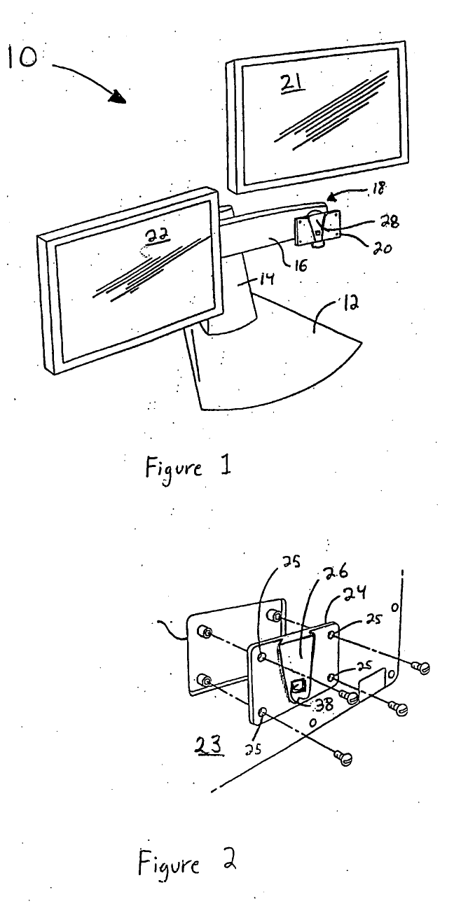

FIG. 1 shows one conventional multi-monitor display system, which is configured to support two monitors 21,22. The display system 10 includes a base 12, an upstanding member 14, an arm member 16 and two support members 18 (only one of which is shown) disposed at opposite ends of the arm member 16.

The upstanding member 14 may be integral with the base 12, but is preferably secured thereto (e.g. by means of a wing nut). Signal and power cables; or a single integral signal/power cable (not shown), may be disposed inside the upstanding member 14 and optionally extend inside the arm member 16, so that the terminals (not shown) emerge adjacent support members 18 for connection to the monitors 21,22. The multi-monitor system 10 may also include a power supply (e.g. a 12 volt power supply) for providing power to the monitors 21, 22. Alternatively, the monitors 21,22 may be connected directly to a conventional electrical outlet, with any necessary circuitry required to adapt the voltage being included in the monitor. Each support member 18 comprises a support element 20 having a socket 28 to support one of the monitors 21, 22.

An owner of system 10 may wish to change one of the monitors, for example monitor 22, to a different, third monitor. Such a different monitor may be procured in one of several ways. For example, the owner may purchase the different monitor as a separate “off-the-shelf” single display monitor. Alternatively, the owner may already be in possession of another display system, possibly a display system having a single detachable monitor that the owner now wishes to integrate into system 10. However procured, before the additional monitor can be used in system 10, there is a need to adapt the different monitor for use therein.

To this end, a kit is now described for adding a monitor to a display system, such as system 10, configured to support multiple monitors. The display system has at least one support member, such as support member 18, and at least one electrical port (not shown in FIG. 1). Referring to FIG. 2, the kit includes a mounting bracket 24 adapted to secure the added monitor to the support member 18, and an electrical connector, described in more detail below, adapted to electrically connect the monitor to the at least one electrical port.

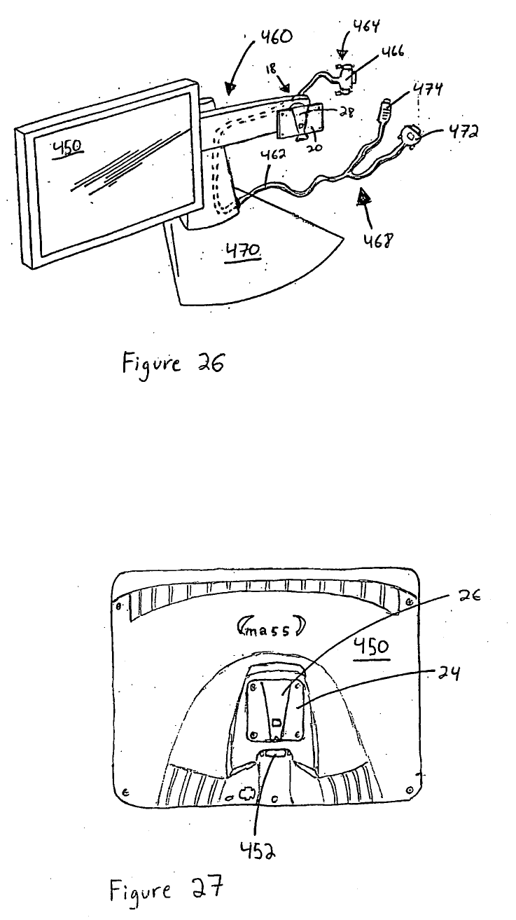

The mounting bracket 24 is affixed to the added monitor, as described in more detail below. Once the mounting bracket is attached thereto, the monitor may matingly engage with the support member 18. The bracket is described first with reference to FIGS. 2 and 4-8. The electrical connector is described later with reference to FIGS. 26 and 28-30.

The mounting bracket 24 of the kit and a monitor 23 to be added to the system 10 after having been adapted for use therein are shown in FIG. 2. Where the monitor 23 has an accessible VESA (Video Electronics Standards Association) mounting hole pattern on its rear surface, the bracket 24 may have holes 25 corresponding to this pattern so that the bracket 24 can be mounted to the monitor 23.

The mounting bracket 24 has a generally wedge-shaped mating member 26 to matingly engage the complementary shaped socket 28 on the support element 20 (shown in FIG. 1) of the support member 18. The mounting bracket 24 may be secured to the monitor 23 by means of screws, bolts, a suitably strong adhesive, or by any other means known in the art. For example, the mounting bracket 24 may be secured to the monitor 23 by way of clamping, such as a conventional clamp or clamps frictionally engaging the edges of the monitor 23 (not shown).

The mating member 26 on the bracket 24 is generally wedge-shaped. In particular, with reference to FIGS. 5, 6 and 8, the mating member 28 has a wider top portion 31 and a narrower bottom portion 33. Preferably, as shown in FIGS. 6 and 8, the mating member 26 is shaped to define projections 30 and grooves 32 along its side edges. The socket 28 (shown in FIG. 9) of support element 20 on support member 18 has complementary grooves 34 and projections 36 (shown in FIG. 9) to matingly engage the projections 30 and grooves 32, respectively, on mating member 26. To cause the mating member 26 to engage the socket 28, the bottom portion 33 is aligned generally with the top portion 35 of the socket 28, and then slid in a generally downward direction. As the bottom portion 33 of the mating member 26 proceeds downwardly into the socket 28, the projections 30 and grooves 32 on the mating member 26 engages the complementary grooves 34 and projections 36 in the socket 28, until the mating member 26 is fully engaged with the socket 28.

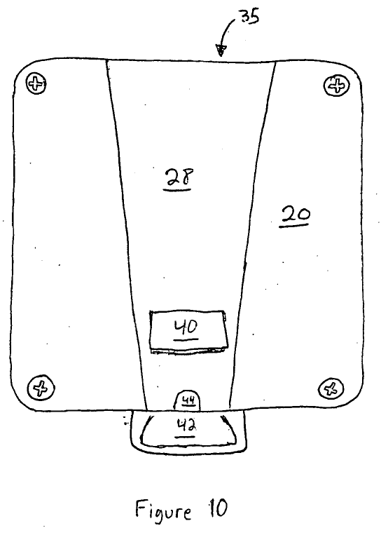

Optionally, as shown in FIGS. 5 and 7, mating member 26 may have an aperture 38 for engaging a detent 40 on the support element 20 (as shown in FIGS. 9 and 10) to maintain the bracket 24 (and thereby monitor 23) in a mounted position. Alternatively, a recess may be used in lieu of the aperture 38. The detent 40 is preferably biased into an engaging position (e.g. by a spring), and has a sloped surface so that it is pushed out of the engagement position as mating member 26 is inserted downwardly into socket 28, and then returns to its engagement position when it is aligned with aperture 38, thereby locking the bracket 24 into engagement with the support element 20. Preferably, a detent lever 42 is operably connected to the detent 40 to allow the detent 40 to be moved out of the engagement position to permit disengagement of the bracket 24 (and thereby the monitor 23) from support element 20 (and thereby from the support member 18). For further stability, a stop 44 may be provided on the socket 28 to engage a notch 46 on the mating member 26.

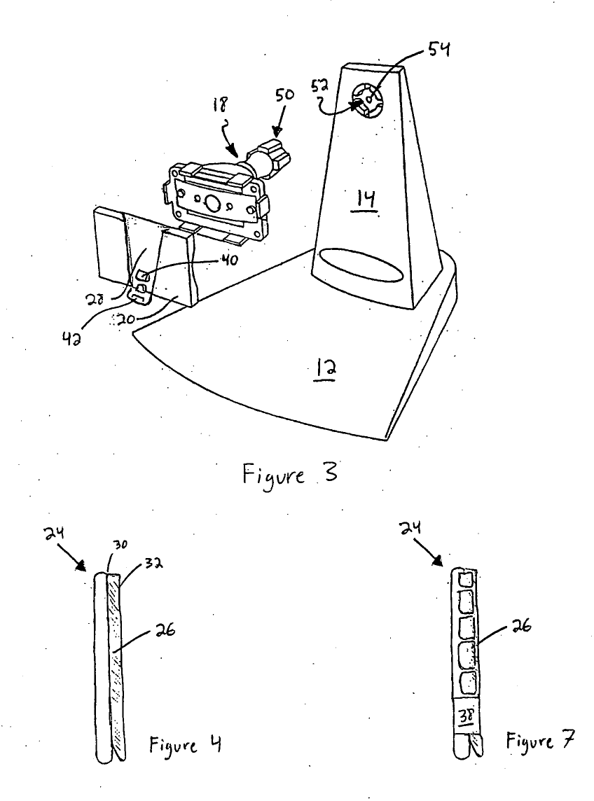

The bracket 24 just described includes a wedge-shaped mating member 26 to engage the socket 28. However, it should be understood that this description of the bracket is exemplary, and that other types of brackets are also consistent with the present invention. For example, the geometry could be reversed in the sense that the bracket may instead include a socket that could mate with a mating member on a support member. In another embodiment, the bracket may not include such a socket or a mating member, but instead may include any device for connecting a monitor to an arm (such as the arm 16). For example, the bracket could include a device similar to the support member 18 having the plug element 50 shown in FIG. 3. Such a bracket could be affixed at one end to the arm and at another end directly to the monitor without the need for any intervening separate plate-like structure, like the structure shown as element 24 in FIG. 2. The bracket can be affixed to either the arm or monitor in any appropriate manner known to those of ordinary skill in the art, such as by screwing and bolting. It is also contemplated that the mounting bracket could also be integrated with the arm in a manner that makes it difficult or impractical to separate the arm and the mounting bracket.

There are several reasons why a user may want to add a monitor to a display system, such as system 10 shown in FIG. 1. As mentioned above, the user may simply want to replace one monitor with another. The monitor that is replaced may be of inferior quality than the added monitor, or the replaced monitor may be broken, for example.

Another reason why a user may want to add the monitor to the display system is to upgrade from one display system to another capable of supporting more monitors. For example, an owner of a one-monitor system may want to upgrade to a two-monitor system. In such case, the owner could simply purchase outright the two-monitor system 10, for example. A more economical approach, however, would be to buy the system 10 but without monitor 21. The second monitor would be obtained from the single monitor system (provided the single monitor is detachable therefrom). With the use of the kit described above, this monitor could be adapted for use in the system 10 devoid of monitor 22. With this approach, only one extra monitor is purchased, instead of two.

If the single-monitor system employs a bracket and support member compatible with bracket 24 and support member 18, there may be no need to include the bracket in the kit, since the existing bracket thereon could mate with the support member 18. However, as discussed in more detail below, especially with reference to FIGS. 26 and 28-30, an electrical connector may still be necessary.

Instead of upgrading at a subsequent date after the purchase of a one-monitor system, a consumer may decide at the outset whether to purchase a single monitor or a two-monitor system, or more generally a multi-monitor system. Multi-monitor systems are typically more costly, and the consumer is often uncertain as to whether such a system is needed. If the customer purchases a single-monitor system, however, and then realizes (after any return period has expired) that a multi-monitor system would be advantageous, the customer may have to buy a complete multi-monitor system, with the monitor from the first, single-monitor system being a wasted expense. Because, as described above, the monitors can be removably mounted to a support structure (e.g. by way of bracket 24 and support members 18), it becomes possible to add one or more monitors to the display system.

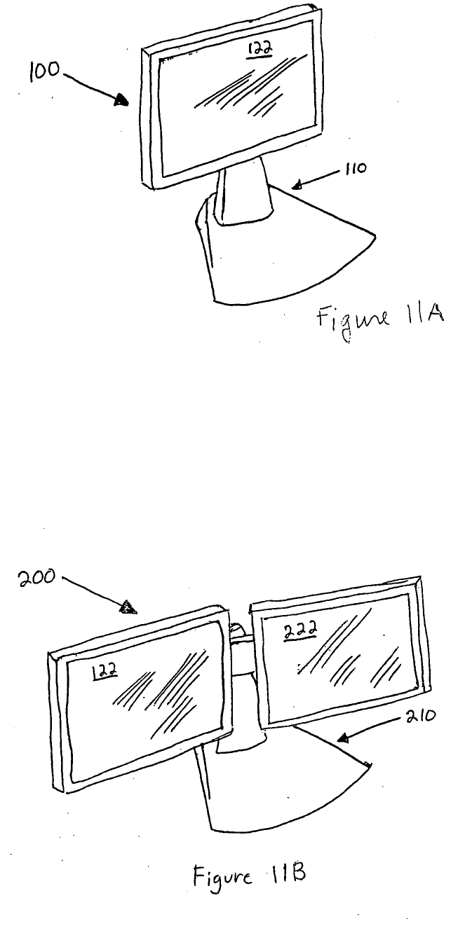

In a first scenario, a customer may have purchased an m-monitor system (where m is the number of monitors), such as the single-monitor system 100 shown in FIG. 11A, in which the support structure is non-modular (i.e. it is not designed to be expanded upon). As used herein, the term “purchased” includes rentals, leases, trades, borrowing, etc., and the term “selling” has a similarly broad connotation. In addition, the term selling includes the transfer of a particular item to a consumer when another item or service is purchased by the consumer. Thus, a “special promotion” where a particular item is given to a consumer “for free” when another item or service is purchased is considered a sale of the particular item, as the term is used herein.

System 100 comprises support structure 110 having a single support member such as support member 18 (not shown in FIG. 11A) and a monitor 122, which has a bracket (such as bracket 24) (not shown in FIG. 11) adapted to matingly engage the support member. The single-monitor system 100 may also include a power supply (not shown), or the monitor 122 may be directly connected to an electrical outlet. Transformers to change 110 volts from an ordinary electrical outlet to 12 V for operation of the monitors can reside in any location that is convenient. Such a location can include a location on or in the monitors, for example.

Signal and power cables (not shown), or a single integral signal/power cable (not shown), may be disposed inside the support structure 110.

The single-monitor system 100 may be upgraded to become a dual-monitor system 200 shown in FIG. 11B by providing an upgrade system comprising an additional monitor 222 having a bracket (such as bracket 24) adapted to matingly engage a support member, and a new support structure 210 having two support members (such as support members 18) each adapted to support a monitor. The new support structure 210 may also have signal and power cables (not shown), or a single integral signal/power cable (not shown) disposed therein. The original support structure 110 may be kept for further use, in which case a new power supply (if necessary) is preferably provided for the new support structure 210, or the original support structure 110 may be discarded or returned to the manufacturer, in which case the original power supply (if any) may be used in the upgraded system. The original monitor 122 may be mounted (by means of its bracket) on one of the two support members of the new support structure 210, with the new monitor 222 also mounted thereon (i.e. on the other support member). Where the original support structure 110 is kept for further use, monitors 122 and 222 may be transferred between the two support structures 110 and 210 as desired.

The method of selling monitors described above may be generalized for any number of monitors in the original and upgraded system as a method in which a customer begins with an m-monitor system, and the upgrade system comprises (n−m) monitors and n support members, where m and n are integers satisfying 0<m<n.

The purchase of an upgrade system that can be integrated with an existing system is more desirable than the purchase of a complete new system because it is generally less expensive (since fewer monitors need to be purchased). Further financial incentives may also be offered to a customer purchasing an upgrade system. For example, the cost structure can be arranged such that the combined cost of an m-monitor system and an upgrade system for preparing an n-monitor system is substantially equal to the cost of an n-monitor system.

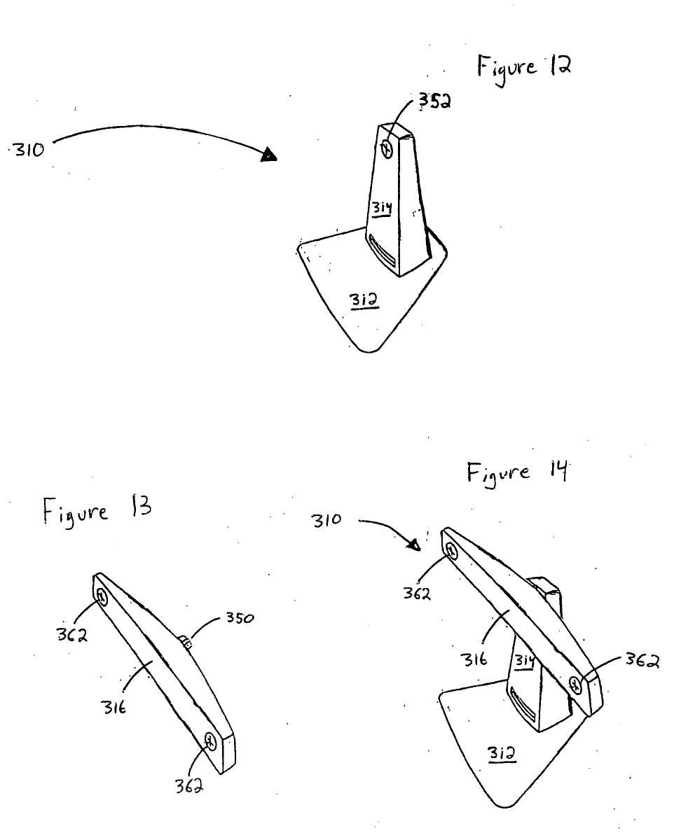

In an alternate embodiment, the original system may be modular, such as the systems shown in FIGS. 3 and 12, which are now described. In FIG. 3, a single-monitor system is shown having a support member 18 with a ball and socket pivot arrangement. The particular construction of the ball and socket pivot structure is described in detail in U.S. Pat. No. 6,343,006 (which is incorporated by reference herein) and will not be further described. In this embodiment, the support member 18 has a plug element 50 adapted to be friction fit into a receiving recess 52 on upstanding member 14. The friction fit is preferably tight enough that plug element 50 is not easily removed from the receiving recess 52 and can support the weight of a monitor, but not so tight as to prevent removal altogether. Preferably, each plug element 50 has a threaded bore 53 (shown in FIG. 32) and is held in place inside the receiving recess 52 by a bolt or screw inserted from the opposite side of upstanding member 14 through an aperture 54 in the receiving recess 52. In such a configuration, when it is desired to remove the plug element 50 from the receiving recess 52, the screw can be removed. It will be appreciated that in a multi-monitor system such as the system 10 shown in FIG. 1, multiple receiving recesses 52 would be provided (e.g. at opposite ends of the arm member 16). The structure of the plug element 50, and of an alternate embodiment of a plug element are described further below.

Another modular system is shown in FIG. 12 and includes a support structure 310 having a base 312 with an upstanding member 314. The upstanding member 314 has a receiving recess 352 adapted to receive a plug element 50 on a support member 18 (as shown in FIG. 3). In other words, the receiving recess 352 is identical to the receiving recess 52 shown in FIG. 3. Thus, a single support member may be mounted to upstanding member 314 so as to provide a single-monitor system (not shown). Referring to FIG. 13, an arm member 316 can be provided with a plug element 350 (identical to that of the plug element 50 on the support member 18 as shown in FIG. 3) to be friction fit into a receiving recess 352. Each arm member 316 is also provided with two receiving recesses 362, which are identical to the receiving recess 352 on the upstanding member 314, and therefore also identical to the receiving recess 52 shown in FIG. 3.

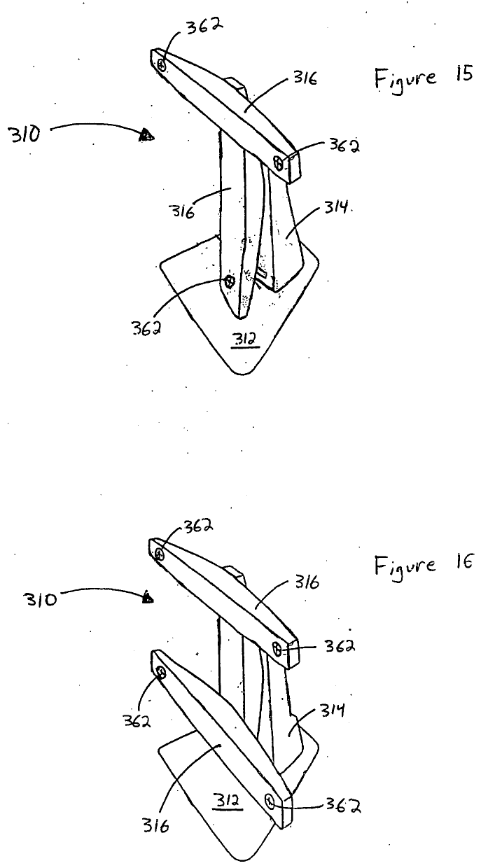

The method described above for upgrading a non-modular system is adaptable to upgrade a modular system, such as those shown in FIGS. 3 and 12-14. For example, a customer could begin with a single-monitor system, so that the support structure 310 simply comprises the base 312 and upstanding member 314, as shown in FIG. 12. Plug element 50 on support member 18 (not shown) is inserted into the receiving recess 352 on the upstanding member 314, and a monitor (not shown) is then matingly engaged with the support member. To upgrade to a dual-monitor system, the upgrade system would comprise a second monitor, one arm member 316, and a second support member 18. The plug element 350 on the arm member 316 is friction fit into the receiving recess 352 on the upstanding member 314, as shown in FIG. 14, so that two receiving recesses 362 are available. The two support members 18 (one from the original system and one from the upgrade system) (not shown) are friction fit into the receiving recesses 362, and the two monitors (one from the original system and one from the upgrade system) (not shown) are then matingly engaged with the two support members 18, resulting in a dual-monitor system.

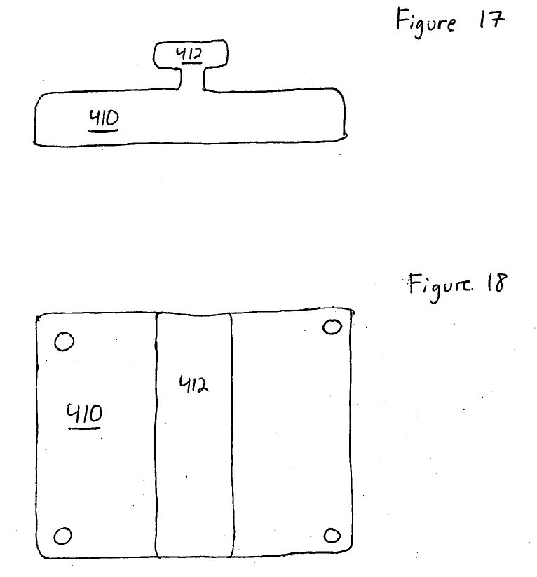

Similarly, a single-monitor system could be upgraded to a three-monitor system by providing an upgrade system comprising two arm members 316, two support members 18, and two monitors. Alternately, a dual-monitor system (as described above) could be upgraded to a three-monitor system by providing one arm member 316, one support member 18, and one monitor. The support structure 310 as adapted to a three-monitor system is shown in FIG. 15, where three receiving recesses 362 are available for three support members (not shown). Support structure 310 is also adaptable to a four-monitor system, as shown in FIG. 16. In fact, where a multi-monitor display system is modular, the method of selling monitors described above may be generalized to include any method in which a customer begins with an m-monitor system, and the upgrade system comprises (n−m) monitors and (n−m) support members, where m and n are integers and 0<m<n.

Alternatively, in the case of a non-modular support structure in which the support member(s) are nonetheless removable (e.g. by way of plug element 50 and receiving recess 52 shown in FIG. 3), the original support structure can be replaced with a new support structure, but the support member(s) from the original system could be reused in the new, upgraded system. (The base from the original support structure, if detachable therefrom, could also be reused as part of the new support structure). Thus, in a system that is non-modular but in which support members from the original support structure are reused with the new support structure, the same method of selling monitors as was used for modular systems may also be employed. In this method, a customer begins with an m-monitor system, and the upgrade system comprises (n−m) monitors and (n−m) support members, where m and n are integers and 0<m<n.

Furthermore, both of the above methods of selling monitors may be adapted to the situation where a customer has not yet purchased a display system, and is uncertain whether to buy, for example, a single-monitor or a dual-monitor system, or is having difficulty deciding whether to buy a dual-monitor system or a three-monitor system. Regardless of the customer's particular situation, according to the method of the present invention, where the customer is trying to decide between an i-monitor system, and an (i+m)-monitor system, the customer is advised to purchase the i-monitor system, wherein the i-monitor system comprises j support members each adapted to support a monitor and i monitors each having a bracket disposed thereon, the bracket adapted to matingly engage a support member, where i and j are integers and 0<i≦j. Preferably i=j, but in some cases it may be desired to provide additional (potentially unnecessary) support members with the initial system. For example, the extra support members could be (e.g. temporarily) mounted elsewhere, such as on a wall, and the monitors moved amongst the support members as desired. The customer may be entirely satisfied with this system, and realize that no additional monitors were needed. In such a case, the customer will be pleased that he or she was not pressured to purchase an (i+m)-monitor system. Alternately, the customer may find that i monitors are insufficient, and that it would have been better to have purchased the (i+m)-monitor system. One embodiment of the method of the present invention includes the further step of offering a customer who has purchased an i-monitor system an upgrade system comprising n support members each adapted to support a monitor and m monitors each having a bracket disposed on the rear surface thereof adapted to matingly engage a support member, where n and m are integers greater than zero. Thus, in a case where a customer would otherwise be dissatisfied because his or her system does not have enough monitors, the method of the present invention avoids such dissatisfaction by providing an upgrade. Financial incentives may also be provided with this method, for example so that the combined price of the initial i-monitor system and the upgrade system is equal to the price of an (i+m)-monitor system. Again, it may be desirable to provide more support members than monitors. Alternatively, it may in some cases be desirable to provide for a system having more monitors than support members. For example, the additional monitors may be selectively mounted in cars, or it may desirable to interchange monitors of various sizes amongst the support members.

It will be appreciated that the above methods of selling monitors will be most effective where the brackets and support members in the first system are compatible with those in the upgrade system. Often, however, manufacturers of monitors used in multi-monitor display systems will each have their own proprietary mounting configuration, and these mounting configurations may not be compatible with one another. This increase the difficulty for a customer who has purchased, for example, a single-monitor system from a first manufacturer and who wishes to upgrade to a dual-monitor system by purchasing an upgrade system from a second manufacturer.

As an example, a customer who has purchased a single-monitor system from Manufacturer A wishes to upgrade to a dual-monitor system. In the present example, however, Manufacturer A does not offer an upgrade system as described above, while Manufacturer B does offer such an upgrade system. The monitor from Manufacturer A may be secured to a support structure by way of screws directly connecting the support structure to the monitor's VESA (or other) mounting hole pattern. Thus, the monitor from Manufacturer A will not have any separate engagement means for attaching to a support structure, and if the monitor is then removed (by unscrewing) from the support structure, the VESA (or other) mounting hole pattern will be exposed. Alternately, the monitor from Manufacturer A may have engagement means, typically (but not necessarily) on the rear side of the monitor, which allow it to be removably supported on the support structure provided by Manufacturer A, but which are unsuitable for supporting it on a support member provided with the upgrade system offered by Manufacturer B. For example, now referring to FIGS. 17 and 18, the engagement means on the monitor from Manufacturer A may comprise a mounting plate 410 having a generally T-shaped engagement member 412. Now referring to FIG. 19, the support structure provided by Manufacturer A would include a receiving element 414 having a generally T-shaped receiving channel 416, corresponding in shape to the T-shaped engagement member 412, with a stop 418 disposed at the bottom of the receiving channel 416. Where the type of support member in the upgrade system provided by Manufacturer B is that of support member 18 having support element 20 as described with respect to FIGS. 9 and 10, mounting plate 410 is clearly incompatible therewith. In either case (i.e. where the monitor provided by Manufacturer A has no engagement means or has incompatible engagement means), the customer will be unable to use the monitor from Manufacturer A with an upgrade system from Manufacturer B that was designed to upgrade an initial system offered by Manufacturer B.

As described above, there may be an initial m-monitor system comprising m monitors and (at least) m support members of a first type (e.g. where the support members have a receiving element such as receiving element 414 described with respect to FIG. 19), each of the monitors having a bracket (e.g. such as a mounting plate 410 described with respect to FIGS. 17 and 18). There is provided a method for upgrading the initial m-monitor system to an n-monitor system (again, m and n are integers satisfying 0<m<n). This method does not require the modification of any of the elements of the initial system.

According to the present invention, the method comprises at least two steps. The first step is that of providing (n−m) support members of a second type, and which are unsuitable for supporting a monitor having a mounting bracket of a first type. For example, a support member 18 having a mounting element 20 as described with respect to FIGS. 9 and 10 is unsuitable for supporting a monitor having a mounting plate 410 described with respect to FIGS. 17 and 18. The second step is providing (n−m) monitors each having a mounting bracket of a second type adapted to support the monitor on a support member of the second type. Continuing the same example, bracket 24 described with respect to FIG. 2 and FIGS. 4 to 7 is adapted to support a monitor on a support member 18 having a mounting element 20 as described with respect to FIGS. 9 and 10. It will be appreciated that the present invention also includes an upgrade kit corresponding to the above-described method. In particular, the upgrade kit will comprise (n−m) support members of a second type, and which are unsuitable for supporting a monitor having a mounting bracket of a first type, and (n−m) monitors each having a mounting bracket of a second type adapted to support the monitor on a support member of the second type.

Where the initial system is modular, the upgrade kit may include a number of arm members (i.e. such as arm member 316 described with respect to FIG. 13) so as to adapt the support structure of the initial system to provide (n−m) additional receiving recesses for the (n−m) additional support members. The plug elements on any arm members and support members will preferably be of the same type as those provided in the initial system, and therefore interoperable therewith. Optionally, however, the upgrade kit may include adaptor means (described further below) for integrating the support members of the second type with the system of support members of the first type.

Alternatively, and particularly where the initial system is non-modular, the upgrade system may include a complete replacement support structure comprising m support members of the first type, and (n−m) support members of the second type. Thus, the display system would have support members of different types. Only the m monitors from the initial system would be reused. However, no modification to these monitors would be necessary.

It is considered preferable, however, to provide a display system where all of the support members are of the same type. Accordingly, the present invention includes a method of retrofitting a monitor for use in a display system, including the step of securing a mounting bracket adapted to matingly engage a support member of a particular type (e.g. support member 18) to the monitor. Typically, but not necessarily, the mounting bracket will be secured to the rear of the monitor. This can be done by way of screws, bolts, adhesive, clamping to an edge or edges of the monitor, or any other suitable means.

Where the monitor to be retrofitted does not include any engagement means (other than a mounting hole pattern, whether VESA or otherwise) the method simply comprises the step of securing a mounting bracket to the monitor, the mounting bracket being adapted to matingly engage a support member. Preferably the mounting bracket is a bracket 24 as described above with respect to FIGS. 2 and 4 to 8, and the support member it is adapted to engage is a support member 18 having a support element 20, as described above with respect to FIGS. 9 and 10.

In another aspect, the method further comprises the step of removing the engagement means from the monitor provided by Manufacturer A before securing the new mounting bracket thereto, if it is necessary (and feasible) to do so. For example, where the monitor provided by Manufacturer A has engagement means such as a mounting plate (e.g. mounting plate 410 shown in FIGS. 17 and 18) screwed to the monitor's VESA (or other) mounting hole pattern, the mounting plate would be unscrewed and removed, and the mounting bracket could then be screwed into the VESA (or other) mounting hole pattern. The mounting bracket is different from the engagement means, in that the engagement means would not permit the monitor to be mounted on a support member provided by Manufacturer B, while the new mounting bracket will permit such mounting. Again, the mounting bracket is preferably a bracket 24 as described above with respect to FIGS. 2 and 4 to 8, and the support member is a support member 18 having a support element 20, as described above with respect to FIGS. 9 and 10.

In some cases, the monitor may have no engagement means at all. For example, the monitor may have an integral stand, or it may be desired to adapt a laptop (or laptop screen) or tablet computer for mounting to a display system (assuming the appropriate electrical connections can be made). In this case, a mounting bracket may be secured to the monitor by way of adhesive. Alternatively, a mounting bracket may be secured to a laptop or tablet computer or monitor by way of a clamp (i.e. to frictionally engage the edge or edges of the monitor), or may provide a support on or within which the bottom edge of the monitor may rest. An additional option is to provide a laptop or tablet computer with a removable mounting bracket (of the same type as the mounting bracket 24 described above). Such a bracket could be easily removed and installed on the laptop or tablet computer, for example by providing a recess on the back of the (e.g.) laptop screen into which the bracket fits. The bracket could be retained in position by, for example, a bayonet-type rotational locking mechanism, or by some other locking means.

While the method has been described with respect to an upgrade from a single-monitor system to a dual-monitor system, it will be appreciated by one skilled in the art that the above method can be used to retrofit a separate monitor for use in a display system having n support members each adapted to support a monitor and m monitors, where m and n are integers and both m and n are greater than zero.

The method described above permits a monitor that was adapted to be mounted to a first display system having support member(s) of a first type to be modified so that it will be suitable for mounting to a second display system having support member(s) of a second type. The present invention also provides a mounting bracket system for such a purpose.

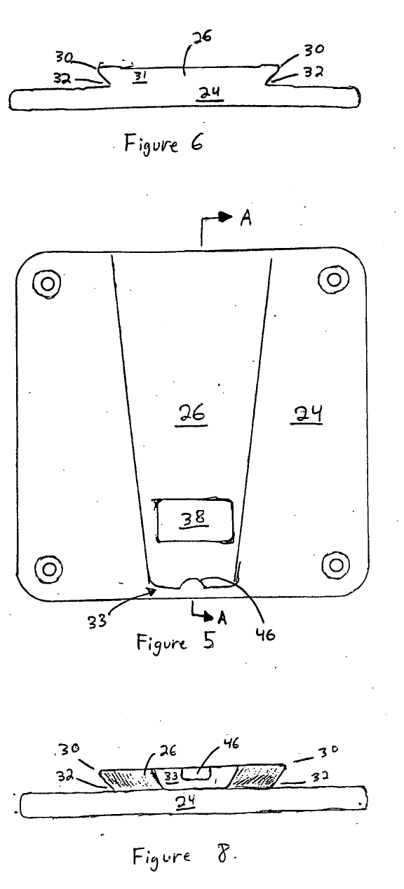

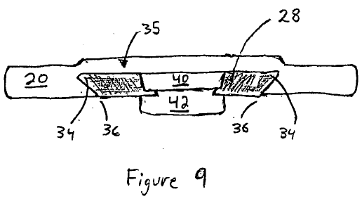

The mounting bracket system of the present invention includes securing means for securing the mounting bracket to a monitor, and mounting means adapted to matingly engage a support member of the second type. In one embodiment, where the monitor to be retrofit has no engagement means other than the VESA (or other) mounting hole pattern (if any), a mounting bracket 24 as described above with reference to FIGS. 4 to 8 is used, so that the mounting means is mating member 26 and the support member of the second type is support member 18 having support element 20 as described with respect to FIGS. 9 and 10. The securing means may then be screws, bolts, adhesives, or any other suitable means.

Alternatively, where the monitor to be retrofit includes engagement means adapted to matingly engage a support member of the first type, the securing means may comprise means for matingly engaging the engagement means on the monitor. For example, the engagement means on the monitor may comprise a mounting plate 410 having a generally T-shaped engagement member 412 as described above with respect to FIGS. 17 and 18. Again, as above, the support member of the first type would then comprise a receiving element 414 having a generally T-shaped receiving channel 416, corresponding in shape to the T-shaped engagement member 412, with a stop 418 disposed at the bottom of the receiving channel 416. Thus, the engagement means (namely the mounting plate 410 with the engagement member 412) is adapted to matingly engage a support member of a first type (which comprises a correspondingly shaped receiving channel 416). (As can be seen, where the support member of the second type is support member 18 having support element 20 as described with respect to FIGS. 9 and 10, the engagement means in the form of mounting plate 410 are incompatible therewith.)

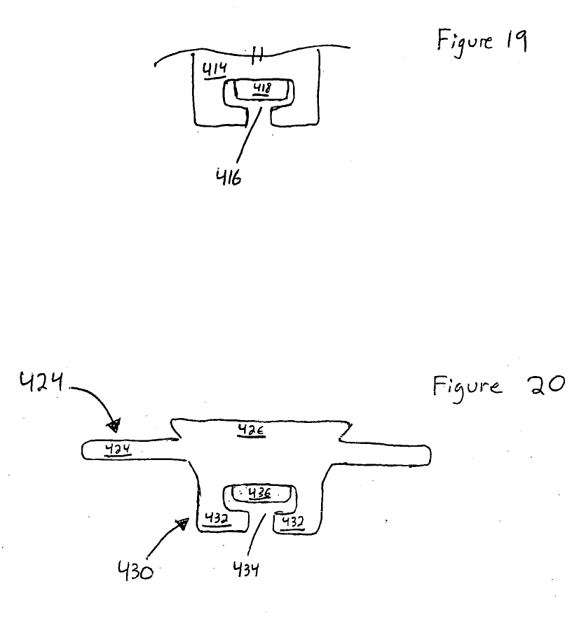

For a number of reasons, it may be impractical to remove the engagement means from a monitor. The engagement means may be integral with the rear facing of the monitor, or may be glued thereto so that it cannot be removed without damaging the monitor. In any situation where it is undesirable or infeasible to remove the engagement means from the monitor, the securing means of the mounting bracket system may comprise means for matingly engaging the engagement means on the monitor. For example, where the engagement means comprises a mounting plate 410 and T-shaped engagement member 412, the securing means would be adapted to matingly engage the T-shaped engagement member 412. Now referring to FIG. 20, mounting bracket system 424 has mounting means, namely generally wedge-shaped mating member 426, and also has securing means 430. Securing means 430 comprises securing element 432, which defines a generally T-shaped channel 434 for receiving the T-shaped engagement member on the monitor (not shown in FIG. 20). A stop 436 is also provided. Thus, the securing means is adapted to matingly engage the engagement means on the monitor. The wedge-shaped mating member 426 is preferably substantially identical to the wedge shaped mating member 26 described with respect to FIGS. 4 to 8, so that the mounting means is thereby adapted to matingly engage a support member of the second type, when the support member of the second type is a support member 18 having a support element 20 as described with respect to FIGS. 9 and 10.

One skilled in the art will recognize that the embodiments described above are exemplary only, and that any number of engagement means, mounting means, securing means and combinations thereof will fall within the scope of the present invention. For example, the facing mentioned above can be affixed to the monitor with screws, clamps, or snaps, for example.

Some single and multi-monitor display systems provide monitors having a single electrical port for receiving both power and video signal. Such monitors are offered, for example, by Mass Engineered Design, Inc., located at 474 Wellington Street West, Toronto, Ontario, Canada M5V 1E3. Now referring to FIG. 27, such a monitor is shown generally at 450. The monitor 450 has a single electrical port 452 for receiving both power and video signal, and also has a mounting bracket 454, which is identical to bracket 24 described with respect to FIGS. 4 to 8.

As stated above, it is also known to provide support structures for single or multi-monitor displays in which signal and power cable(s) are associated with a support member (for example by disposing the cable(s) inside a hollow support structure so that they emerge adjacent a support member for supporting a monitor). Where the monitors to be used with a particular support structure have a single electrical port for receiving both power and video signal (such as those provided by Mass Engineered Design, Inc.), a single combined video signal/power cable may be used for each monitor. Such a cable would terminate at one end in a single connector element for connecting to the single port on the monitor, and at a second end in a separate video signal connection element and power connection element for connection to a computer system and a power supply, respectively. Mass Engineered Design, Inc. offers such cables in association with its monitors. Now referring to FIG. 26, a support structure for a multi-monitor display system is indicated generally at 460. The support structure 460 has two support members 18 (only one of which is shown) and is designed for use with monitors 450 having a single electrical port 452 for receiving both power and video signal. Accordingly, the support structure 460 has disposed therewithin two combined video signal/power cables 462 (again, only one is shown). A first end 464 of the combined video signal/power cable 462 emerges adjacent a support member 18, and is adapted by means of a connector element 466 to transmittingly engage a single electrical port 452 on a monitor 450 so as to transmit both an electrical power supply and a video signal to that monitor 450. A second end 468 of combined video signal/power cable 462 emerges adjacent the base 470 of the support structure 460, and is adapted to transmittingly engage both a video signal output port on a computer (by way of the signal connector 472) and the output of a power supply (by way of the power connector 474). The power supply may be integral with the computer system, or may be a separate unit.

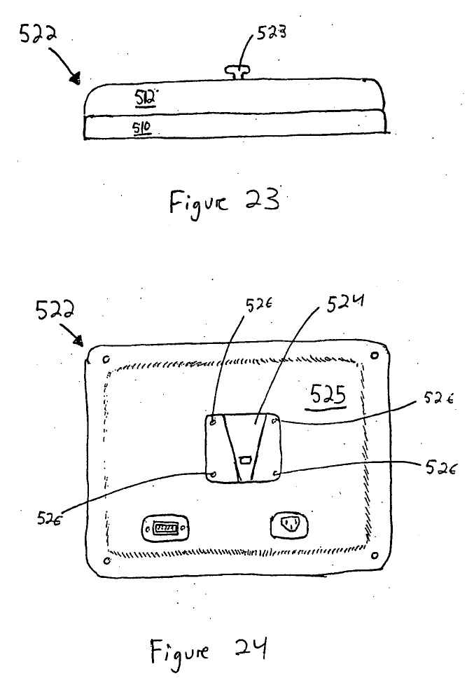

In some cases, it is sought to upgrade a display system incorporating monitor(s) having separate video signal input and power input ports (such as the monitor 522 described below with respect to FIG. 22) using additional monitors having a single electrical port for receiving both power and video signal (such as the monitor 450 described above with respect to FIG. 27), or vice versa. In either case, where the support structure for the display system has signal and power cable(s) (whether combined or separate, as the case may be) that are associated with the support members, there will be an incompatibility between the monitors sought to be added, and the cabling in the existing display system. In particular, if the existing display system has cabling for dual port (i.e. separate signal and power ports) monitors, it will be incompatible with single port (i.e. for both signal and power) monitors. Conversely, if the existing display system has cabling for single port monitors, it will be incompatible with dual port monitors. While the method and mounting bracket system described above will permit various types of monitors to be physically mounted on various display systems for which they were not originally designed, where the cabling is incompatible with the monitor ports, the electrical connections may pose a difficulty. While it may be possible to connect the monitors directly to the computer system and power supply using cables that are independent of the support structure, this results in an unattractive appearance, as the cables will no longer be concealed within the support structure, and there may also be a visible “loose end” of a cable included with the support structure.

Accordingly, the present invention also provides a kit for adapting a monitor for use in a display system having at least one support member for supporting a monitor where each support has at least one electrical port associated therewith for transmitting at least one of power and video signal to a corresponding monitor. In particular, the kit comprises a mounting bracket arrangement (such as mounting bracket system 424 as described with respect to FIG. 20, or a bracket 24 as described with respect to FIGS. 4 to 8), and an electrical connector cable for connecting the at least one electrical port associated with the support member to at least one electrical port on a monitor. Preferably, the mounting bracket has a generally wedge-shaped mating member such as the mating member 26 on the bracket 24 described with respect to FIGS. 2 and 4 to 8.

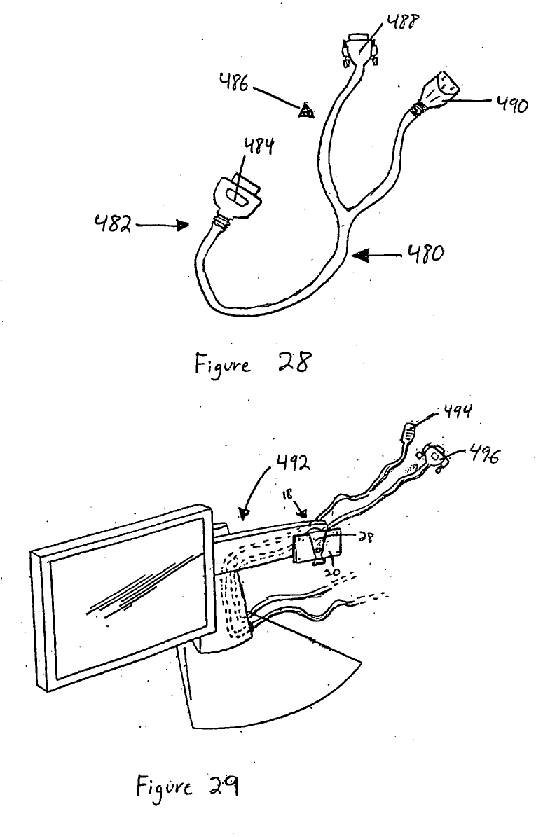

In one embodiment, the electrical connector cable included with the kit is adapted to connect a monitor having separate electrical ports for power and video signal to a single electrical port for transmitting both power and video signal. Now referring to FIG. 26, support member 18 on support structure 460 has an associated single electrical port, in the form of connector element 466, for transmitting both power and video signal. As noted above, such a port is incompatible with a dual-port monitor. With reference to FIG. 28, a first embodiment of an electrical connector cable for use in the kit of the present invention is shown generally at 480. The first embodiment of the electrical connector cable 480 is adapted at a first end 482 to connect to the single electrical port associated with the support member (i.e. connector element 466 in FIG. 26) by means of a corresponding single connector element 484. It should be understood that the location where this connection is made or resides may be anywhere that is convenient, such as near the support member 18, but also near or in the base 470, for example. At its second end 486, the electrical connector cable 480 is adapted to connect to both a video signal port on a monitor (by means of a video signal connection element 488) and a power supply port on a monitor (by means of a power connection element 490).

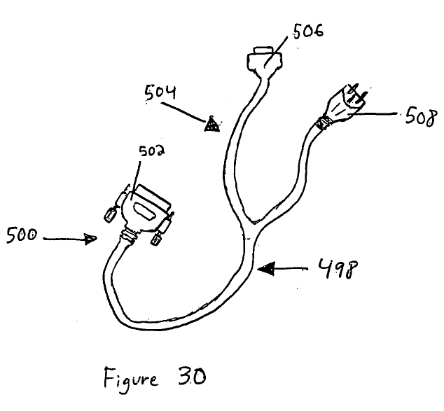

In a second embodiment, the electrical connector cable included with the kit is adapted to connect a monitor having a single electrical port for receiving both power and video signal to two separate electrical ports, one for transmitting power and one for transmitting video signal. Now referring to FIG. 29, support structure 492 has two support members 18 (only one of which is shown). Each support member 18 has two electrical ports associated therewith, a first electrical port (a power connection element 494) for transmitting power to a monitor, and a second electrical port (in the form of a video signal connector element 496) for transmitting video signal to a monitor. In FIG. 30, a second embodiment of an electrical connector cable for use with the kit is shown generally at 498. The second embodiment of the electrical connector cable is adapted at a first end 500 (by way of single connector element 502) to connect to a single electrical port on a monitor (such as the port 452 on the monitor 450 described with respect to FIG. 27). The second embodiment of an electrical connector cable 498 is adapted at a second end 504 to transmittingly engage the first electrical port (by way of a video signal connection element 506) and the second electrical port (by way of a power connection element 508) associated with the at least one support member. Again, the locations at which these connections are made or reside may be anywhere that is convenient.

It will be appreciated by one skilled in the art that whether the single connector element 484, 502, the video signal connection element 488, 506, and the power connection element 490, 508 are male or female will be determined by whether the port to which they are to be connected is male or female. Similarly, the particular type of ports used will be selected based on the ports associated with the support structure and present on the monitor(s) to be connected. Accordingly, there are numerous possible variations on the two basic embodiments described above, depending on the particular types of ports and connector elements used, and all such variations are intended to be included within the scope of the present invention. It is within the contemplation of the inventor that there may be numerous particular methods by which an electrical connector cable may be configured to transmit or receive separate video signal and power supply inputs at one end and receive or transmit both signals through a single electrical port at the other end.

As noted above, it is possible that a monitor may have a rear facing having engagement means that are integral or otherwise substantially non-removable. The method above provides for securing a mounting bracket to the monitor, and the associated mounting bracket system may comprise securing means for matingly engaging the engagement means on the monitor. An alternate method for retrofitting a monitor so as to adapt it for use in a display system having at least one support member is now described. This method is suitable for use with a monitor having engagement means disposed on the rear facing wherein the engagement means are integral with or otherwise substantially non-removable from the rear facing.

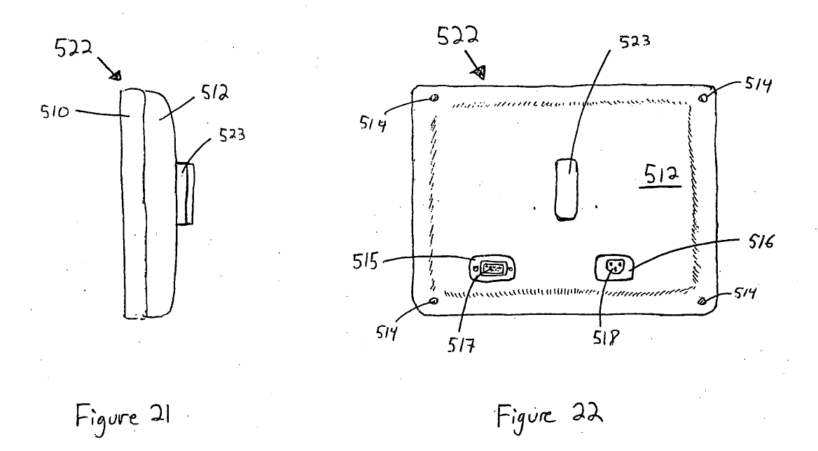

Now referring to FIGS. 21 to 23, a monitor comprising a front (i.e. screen side) facing 510 and a first rear facing 512 is indicated generally at 522. The first rear facing 512 is secured to the front facing 510 by means of screws 514. The first rear facing 512 has apertures 515 and 516 defined therein, in order to render the video signal port 517 and the electrical power supply port 518 accessible for connecting signal and power supply cables (not shown) to the monitor 522. An engagement means, which in this case comprises a generally T-shaped engagement member 523, is integrally formed with the first rear facing 512 of monitor 522. The T-shaped engagement member 523 is adapted for mating engagement with a receiving element such as a receiving element 414 having a generally T-shaped receiving channel 416 as described in relation to FIG. 19. Accordingly, the T-shaped engagement means is unsuitable for use with a support member having a support element 20 of the type described with respect to FIGS. 8 and 9. Because the T-shaped engagement member 523 is integral with the first rear facing 512, it cannot be easily removed.

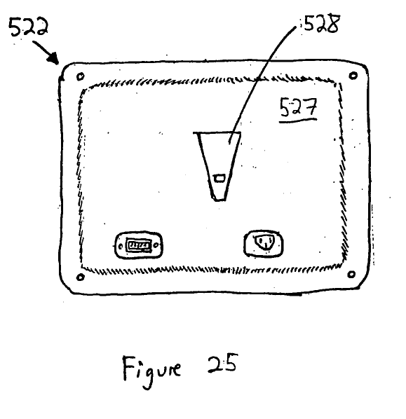

In a method according to the present invention, the first rear facing 512 is removed from the monitor 522, in the present example by unscrewing the screws 514 and then lifting the first rear facing 512 away from the monitor 522. A second rear facing 525 having a mounting bracket 524 on its outer surface is then installed on the monitor 522, as shown in FIG. 24. The mounting bracket 524 is preferably the bracket 24 described above with respect to FIGS. 2 and 4 to 8, and is therefore adapted to matingly engage a support member having a support element of the type described with respect to FIGS. 8 and 9. Mounting bracket 524 may be secured to the second rear facing 525 by way of screws 526, or (not shown) by a suitably strong adhesive. In a preferred embodiment, the second rear facing 525 has a VESA mounting hole pattern defined thereon, and the mounting bracket 524 is secured thereto by screws 526. Alternately, as shown in FIG. 25, a second rear facing 527 may be provided with an integral mating member 528 that is substantially identical to the mating member 26 described above.

As was described above, it is possible that there may be an incompatibility between the cabling provided in a support structure for a display system, and the video signal and power port(s) on a monitor sought to be integrated with the display system (such as where each support member in the display system has a single electrical port and the monitor is a dual port monitor, or vice versa). One solution is to provide an adaptor kit including an electrical connector cable (such as the electrical connector cables 480, 498 described with respect to FIGS. 28 and 30, respectively). Alternately, where the first rear facing of a monitor is to be removed and replaced by a second rear facing, as in the above method, the method may comprise additional steps to adapt the monitor for use with a display system with which its power and video signal port(s) would otherwise be incompatible.

As shown in FIG. 22, the rear facing 512 of the monitor 522 defines two apertures 515 and 516 for exposing two separate electrical ports, namely the video signal port 517 and the electrical power supply port 518. It is also possible that a rear facing may define a single aperture exposing both electrical ports (not shown). The monitor 522 has power receiving circuitry and video signal receiving circuitry (not shown). The electrical power supply port is connected to the power receiving circuitry for transmitting power to the monitor 522, and the video signal port 517 is connected to the video signal receiving circuitry for transmitting video signal to the monitor 522. Where the support structure with which the monitor 522 is to be integrated provides only a single electrical port, the monitor 522 cannot be directly connected thereto.

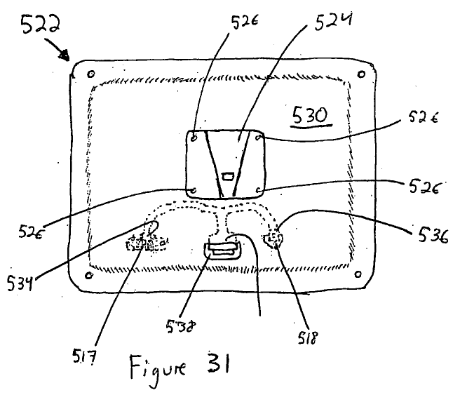

In such a case, the method described above may further comprise the step, before installing the second rear facing on the monitor 522, of connecting the power receiving circuitry and video signal receiving circuitry to a single combined electrical port so that both power and video signal may be transmitted to the power receiving circuitry and video signal receiving circuitry, respectively, by means of the single combined electrical port. This process may be as simple as, for example, connecting an electrical connector cable, such as a shortened version of electrical connector cable 480 described with respect to FIG. 28, to the video signal port 517 and electrical power supply port 518. Now referring to FIG. 31, a monitor 522 is shown with a second rear facing 530 secured thereto. A mounting bracket 524 is secured thereto by screws 526. Prior to attaching the second rear facing 530 to the monitor 522, an electrical connector cable 532 (shown in relief was installed. In particular, the electrical connector cable 532 has a video signal connector element 534, which was connected to the video signal port 517 on the monitor 522, and a power connection element 536, which was connected to the electrical power supply port 518 on the monitor 522. The second rear facing 530 has an aperture 538 adapted to expose only a single combined electrical port for receiving both power and video signal. The electrical connector cable terminates in a single combined electrical port 540 adapted for receiving both power and video signal, and this single combined electrical port 540 is arranged to be accessible via the aperture 538 in the second rear facing 530. The second rear facing 530 may be secured to the monitor 522 once the electrical connector cable 532 has been installed. The second rear facing 530 may be shaped to accommodate the additional space occupied by the connector cable 532 when installed.

One skilled in the art will appreciate that various other ways of connecting the power receiving circuitry and video signal receiving circuitry to a single combined electrical port are intended to be included within the scope of the present invention. It may similarly be possible to adapt a single-port monitor connecting the power and video signal receiving circuitry to separate power and video signal ports.

Referring again to FIG. 3, it will be recalled that support member 18 has a plug element 50 adapted to be received within a correspondingly shaped receiving recess 52. Thus, support member 18 could be removably mounted to a support structure, so that it could be removed and a different support member installed in its place. This would permit a support member of a first type (i.e. adapted to support a monitor having a mounting bracket of a first type) to be replaced with a support member of a second type (i.e. adapted to support a monitor having a mounting bracket of a second type). Replacing support members in this way could avoid the need for modifications to the monitors themselves (at least where the support members are easily removable). However, different manufacturers of display systems may have different (i.e. proprietary) means for mounting their respective support members to their associated support structures, and the means used by one manufacturer may not be compatible with those of another manufacturer.

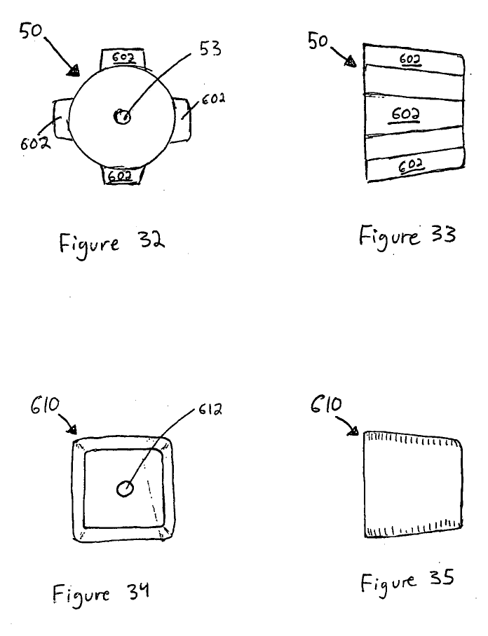

For example, the plug element 50 shown in greater detail in FIGS. 32 and 33 has a generally frusto-conical shape, with rectangular stabilizing members 602 disposed at 90 degree intervals about the exterior surface. A threaded bore 53 is provided at the center of the plug element 50, as described above. In contrast, now referring to FIGS. 34 and 35, an alternate plug element 610 has a generally (slight) frusto-pyramidal shape, with smoothed edges, and also has a threaded bore 612 defined therein. As can be seen by reference to FIGS. 32 to 35, a receiving recess shaped to receive a plug element 50 will not accommodate an alternate plug element 610, and vice versa. Thus, if Manufacturer C secures support members to a support structure by means of plug element 50, and Manufacturer D secures support elements to a support structure by means of alternate plug element 610, it will not be possible to integrate support elements provided by Manufacturer D with the support structure of a display system provided by Manufacturer C.

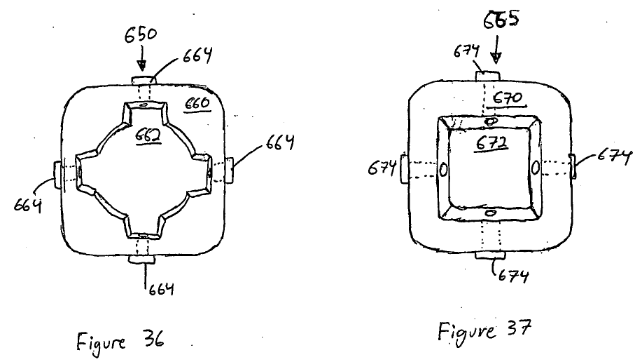

Particularly where a support structure is modular, such as that described with respect to FIGS. 12 to 16, it is desirable to provide for the interchangeability of support members having different types of plug elements. Accordingly, the present invention provides for an adaptor for integrating support members of a first type with support members of a second type. With reference now to FIGS. 36 and 37, an adaptor member 650 may have a first end 660 having a first receiving recess 662 shaped to accommodate a first type of plug element (in this case plug element 50), and a second end (not shown) comprises a second type of plug element (in this case plug element 610). Thus, adaptor member 650 will permit a support member having a plug element 50 (FIGS. 3, 32 and 33) to be integrated with a support structure having receiving recesses designed to accommodate a plug element 610 (FIGS. 34 and 35). Conversely, adaptor member 665 has a first end 670 having a second receiving recess 672 shaped to accommodate a second type of plug element (in this case plug element 610), and a second end (not shown) comprises a first type of plug element (in this case plug element 50). Thus, adaptor member 665 will permit a support member having a plug element 610 (FIGS. 34 and 35) to be integrated with a support structure having receiving recesses designed to accommodate a plug element 50 (FIGS. 3, 32 and 33). In order to secure the relevant plug element within the receiving recess 662, 672, each adaptor member 650, 665 is provided at its first end 660, 670 with four set-screws 664, 674, respectively.

Three basic examples of embodiments of the invention are provided as follows.

In Examples 1 and 2, a user begins with a single monitor system comprised of the following components: a Mass Engineered Design, Inc. 15 inch or any other size monitor having a proprietary signal/power connector, a column with an integrated signal/power cable and a quick release mounting system (for the monitor), a base which bolts to the column with a single wing nut, and an external +12 volt power supply.

In Example 1, the user is supplied a second Mass Engineered Design, Inc. 15 inch or any other size monitor, a replacement column, and a dual arm which has a dual integrated signal/power cable installed and one quick release assembly. The quick release assembly, base and power supply are reused from the original single monitor purchase, creating a dual monitor system.

In Example 2, the user is supplied with a second Mass Engineered Design, Inc. 15 inch or any other size monitor and complete dual monitor stand including quick release assemblies, power supply and base. This allows the user to operate the single monitor by transferring a monitor between the dual and single stands.

Example 3: The Mass Engineered Design, Inc. stand or structure utilizes a quick release assembly for ease of monitor mounting. By supplying an adaptor plate that interfaces between a monitor's VESA mounting hole pattern and the Mass Engineered Design, Inc. quick release assembly, any manufacturer's monitor could be used in the systems described above. This would allow a user to use a previously purchased monitor with the Mass Engineered Design, Inc. stand, creating a hybrid multi-screen system.

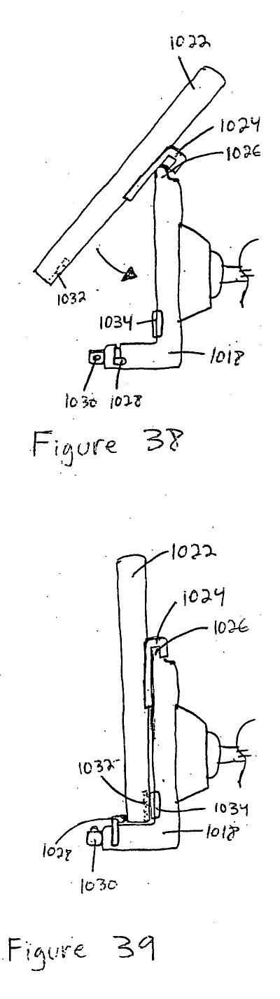

As was noted above, another means for securing a monitor is “hook and latch” means. Referring now to FIGS. 38 and 39, a monitor support 1018 and a monitor 1022 are shown. The monitor 1022 has a hook member 1024 disposed adjacent its rear surface. The hook member 1024 is adapted to pivot about the upper portion 1026 of the monitor support 1018. The monitor support 1018 also has a latch 1028 to assist in retaining the monitor in a vertical position.

In operation, a monitor 1022 is positioned so that the hook member 1024 rests on the upper portion 1026 of the monitor support 1018, as shown in FIG. 38. The monitor 1022 is then pivoted downward into a vertical position, as shown in FIG. 39. The latch 1028 is then moved into a retaining position (also shown in FIG. 39), for example by rotating the latch by way of knob 1030. Other types of fastening means could also be used.

It is envisioned that the various methods and structures described above may be adapted for use with systems enabling automatic electrical connection of a monitor, without departing from the scope of the present invention. For example, it is within the contemplation of the inventor that mating members (similar to the mating member 24 described above with respect to FIGS. 2 and 4 to 8) and correspondingly shaped sockets (similar to the socket 28 described above) may each be equipped with electrical contacts, so that a monitor will automatically receive electrical communication (i.e. video signal from a computer and electrical power from a power supply) upon mating engagement of the mating member with the socket.

In another example, referring to FIGS. 38 and 39, a monitor 1022 may have one or more electrical contact elements 1032 (shown in relief), and the monitor support 1018 may have one or more corresponding electrical contact elements 1034. Accordingly, when the monitor 1022 is moved into the vertical position shown in FIG. 39, it will automatically be in electrical communication with the relevant computer system and power supply (if any).

It will be appreciated by one skilled in the art that numerous variations and modifications may be made to the embodiments and methods described above without departing from the scope of the present invention. For example, one skilled in the art will recognize that a wide variety of support members, brackets, plug elements and receiving recesses may be used within the scope of the present invention. For example, the use of a “hook and latch” arrangement is contemplated within the scope of the present invention. All such variations and modifications are intended to be encompassed within the scope of the present invention as defined by the appended claims. Also, while some embodiments described above included a base, it should be understood that a base may not be necessary in all applications. For example, it is consistent with the principles of the present invention to mount the monitors, with or without the support arms, to walls, ceilings of buildings or vehicles, which applications may not require the use of a base. Furthermore, while many of the above described monitors have been shown in the drawings in landscape position, it should be understood that they could also be mounted in portrait position. Alternatively, or in addition, the monitors, once mounted, may be able to rotate from one position to the other.

1. A kit for adding a monitor to a display system configured to support multiple monitors, the display system having at least one support member, and at least one electrical port, the kit comprising:
a mounting bracket adapted to secure the monitor to the at least one support member; and
an electrical connector adapted to electrically connect the monitor to the at least one electrical port.

2. The kit of claim 1, wherein each support member has at least one electrical port associated therewith.

3. The kit of claim 2, wherein the mounting bracket comprises a generally wedge-shaped mating member adapted to engage a correspondingly shaped socket on the at least one support member.

4. The kit of claim 2, wherein the mounting bracket has a generally wedge-shaped socket and the support member has a correspondingly shaped mating member for inserting into the socket.

5. The kit of claim 2, wherein the at least one electrical port transmits at least one of power and video signal to a corresponding monitor.

6. The kit of claim 5, wherein the at least one electrical port comprises a single electrical port for transmitting both power and video signal to a corresponding monitor, and the electrical connector cable is adapted at a first end to transmittingly engage the single electrical port, and adapted at a second end to transmittingly engage both a video signal port and a power supply port on the corresponding monitor.

7. The kit of claim 5, wherein the at least one electrical port comprises a first electrical port for transmitting power to a monitor and a second electrical port for transmitting video signal to a monitor, and the electrical connector cable is adapted at a first end to transmittingly engage a single electrical port on the monitor, the single electrical port for receiving both power and video signal, and adapted at a second end to transmittingly engage both the first and second electrical ports associated with the at least one support member.

8. The kit of claim 2, further comprising a rear facing having affixed thereto the mounting bracket.

9. The kit of claim 2, wherein the display system is configured to support two monitors.

10. The kit of claim 2, wherein the mounting bracket is secured to the monitor by fasteners.

11. The kit of claim 1, wherein the mounting bracket is secured to the monitor by adhesive.

12. A method of retrofitting a monitor for a display system configured to support multiple monitors, the display system having at least one support member, the method comprising:
securing a mounting bracket to the monitor; and
mounting the monitor on the display system by securing the mounting bracket to the at least one support member.

13. The method of claim 12, wherein the monitor is an off-the-shelf single display monitor.

14. The method of claim 12, further comprising the step of removing an engagement means connected to the monitor before securing the mounting bracket thereto.

15. The method of claim 14, wherein the engagement means is unsuitable for supporting the monitor on the one support member.

16. The method of claim 15, wherein the engagement means is secured to a first rear facing and the mounting bracket is secured to a second rear facing, the step of removing the engagement means including removing the first rear facing, and the step of securing a mounting bracket including securing the second rear facing to the monitor.

17. The method of claim 16, wherein the step of removing the first rear facing includes unscrewing.

18. The method of claim 16, wherein the step of securing the second rear facing includes screwing.

19. The method of claim 12, wherein the step of securing the mounting bracket includes securing the mounting bracket with at least one of screws and adhesive.

20. The method of claim 12, wherein the mounting bracket has a generally wedge-shaped mating member and the one support member has a correspondingly shaped socket for receiving the mating member.
